(19) United States
(12) Patent Application Publication
(10) Pub. No.: US 2026/0082770 A1
(43) Pub. Date: Mar. 19, 2026

(54) DISPLAY PANEL AND ELECTRONIC APPARATUS INCLUDING THE SAME

(71) Applicant: SAMSUNG DISPLAY CO., LTD., Yongin-si (KR)

(72) Inventors: Junhee Lee, Yongin-si (KR); Yechan Choi, Yongin-si (KR); Changwook Kim, Yongin-si (KR); Kookhyun Choi, Yongin-si (KR); Beohmrock Choi, Yongin-si (KR)

(21) Appl. No.: 19/286,593

(22) Filed: Jul. 31, 2025

(30) Foreign Application Priority Data
Sep. 13, 2024 (KR) 10-2024-0126172

(51) Int. Cl. H10K 59/122; H10K 59/131

(52) U.S. Cl. CPC H10K 59/122; H10K 59/131

(57) ABSTRACT

A display panel including: a substrate; a pixel electrode disposed on the substrate; a pixel-defining layer having an opening, wherein the pixel-defining layer covers an edge of the pixel electrode, and the opening exposes a center of the pixel electrode; and a first line positioned between the substrate and the pixel electrode and having a first portion overlapping the pixel-defining layer and a second portion overlapping the opening, wherein, when viewed from a direction perpendicular to the substrate, a shape of the first portion differs from a shape of the second portion.

### CROSS-REFERENCE TO RELATED APPLICATION

This application claims priority under 35 U.S.C. § 119 to Korean Patent Application No. 10-2024-0126172, filed on Sep. 13, 2024, in the Korean Intellectual Property Office, the disclosure of which is incorporated by reference herein in its entirety.

### TECHNICAL FIELD

One or more embodiments of present disclosure relate to a display panel and an electronic apparatus including the display panel. More specifically, the disclosure relates to a display panel capable of displaying high-quality images and an electronic apparatus including the display panel.

### DESCRIPTION OF THE RELATED ART

Display panels, including organic light-emitting display panels, typically incorporate thin-film transistors positioned beneath the organic light-emitting elements. These transistors regulate the luminance of the organic light-emitting elements by responding to data signals or similar inputs, thereby controlling the brightness of the corresponding elements.

### SUMMARY

In conventional display panels, the quality of images produced by organic light-emitting diodes positioned at the top can be adversely affected by the underlying structure of thin-film transistors, leading to image degradation.

One or more embodiments of the disclosure include a display panel on which high-quality images may be displayed, and an electronic apparatus including the display panel. However, the embodiments described herein are merely examples, and the scope of the disclosure is not limited thereto.

Additional aspects will be described in part in the following description, will be apparent from the description, or may be learned by practice of the embodiments of the disclosure.

According to one or more embodiments of the disclosure, there is provided a display panel comprising: a substrate; a pixel electrode disposed on the substrate; a pixel-defining layer having an opening, wherein the pixel-defining layer covers an edge of the pixel electrode, and the opening exposes a center of the pixel electrode; and a first line positioned between the substrate and the pixel electrode and having a first portion overlapping the pixel-defining layer and a second portion overlapping the opening, wherein, when viewed from a direction perpendicular to the substrate, a shape of the first portion differs from a shape of the second portion.

When viewed from the direction perpendicular to the substrate, the first portion is straight in a direction in which the first line extends, and the second portion is curved.

When viewed from the direction perpendicular to the substrate, the second portion is a repeating curve.

The display panel further comprising a second line positioned between the substrate and the pixel electrode and having a third portion and a fourth portion, wherein the third portion overlaps the pixel electrode and the pixel-defining layer, the fourth portion overlaps the opening, and, when viewed from the direction perpendicular to the substrate, a shape of the third portion differs from a shape of the fourth portion.

When viewed from the direction perpendicular to the substrate, each of the first portion and the third portion is straight in a direction in which the first line extends, and each of the second portion and the fourth portion is curved.

When viewed from the direction perpendicular to the substrate, each of the second portion and the fourth portion is a repeating curve.

The second portion has a first convex portion protruded in a direction toward the second line, and the fourth portion has a second convex portion protruded in a direction away from the first line.

A first imaginary straight line passing through the first convex portion and perpendicular to the direction in which the first line extends is spaced apart from a second imaginary straight line passing through the second convex portion and perpendicular to the direction in which the first line extends.

The second portion has first convex portions protruded in a direction toward the second line, and the fourth portion has second convex portions protruded in a direction away from the first line.

First imaginary straight lines passing through the first convex portions and perpendicular to the direction in which the first line extends are spaced apart from second imaginary straight lines passing through the second convex portions and perpendicular to the direction in which the first line extends.

The first imaginary straight lines and the second imaginary straight lines are alternately arranged in the direction in which the first line extends.

The first line includes a driving voltage line and the second line includes a data line.

When viewed from the direction perpendicular to the substrate, the first line has a fifth portion that overlaps the opening and is spaced apart from the second portion in the opening, wherein the second portion and the fifth portion are connected to the first portion.

When viewed from the direction perpendicular to the substrate, each of the first portion and the third portion is straight in the direction in which the first line extends, and each of the second portion, the fourth portion, and the fifth portion is curved.

When viewed from the direction perpendicular to the substrate, each of the second portion, the fourth portion, and the fifth portion is a repeating curve.

The second portion has a first convex portion protruded in a direction toward the second line, the fifth portion has a third convex portion protruded in the direction toward the second line, and the fourth portion has a second convex portion protruded in a direction away from the first line.

A first imaginary straight line passing through the first convex portion and perpendicular to a direction in which the first line extends is spaced apart from a second imaginary straight line passing through the second convex portion and perpendicular to the direction in which the first line extends, and a third imaginary straight line passing through the third convex portion and perpendicular to the direction in which the first line extends coincides with the first imaginary straight line.

The second portion has first convex portions protruded in a direction toward the second line, the fifth portion has third convex portions protruded in the direction toward the second line, and the fourth portion has second convex portions protruded in a direction away from the first line.

First imaginary straight lines passing through the first convex portions and perpendicular to a direction in which the first line extends are spaced apart from second imaginary straight lines passing through the second convex portions and perpendicular to the direction in which the first line extends, and third imaginary straight lines passing through the third convex portions and perpendicular to the direction in which the first line extends coincide with the first imaginary straight lines.

The first imaginary straight lines and the second imaginary straight lines are alternately arranged in the direction in which the first line extends.

The display panel further comprising an auxiliary line disposed on a layer different from a layer on which the first line and the second line are disposed and positioned between the first line and the second line in the opening when viewed from the direction perpendicular to the substrate.

The auxiliary line is isolated.

According to one or more embodiments of the disclosure, there is provided a display panel comprising: a substrate; a pixel electrode disposed on the substrate; a pixel-defining layer configured to define an opening that exposes a portion of the pixel electrode, wherein the pixel-defining layer at least partially covers the pixel electrode; and a conductive line positioned between the substrate and the pixel electrode, the conductive line including a first region overlapping the pixel-defining layer and a second region overlapping the opening, wherein, in a plan view, the first region has a shape distinct from the shape of the second region.

According to one or more embodiments of the disclosure, an electronic apparatus includes one of the display panels described above.

These and/or other aspects will become apparent and more readily appreciated from the following description of the embodiments, the claims, and the accompanying drawings.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view schematically illustrating a display panel according to an embodiment of the disclosure;

FIG. 2 is a lateral view schematically illustrating the display panel of FIG. 1;

FIG. 3 is an equivalent circuit diagram of a pixel included in the display panel of FIG. 1;

FIG. 4 is a plan view schematically illustrating a conductive layer included in the display panel of FIG. 1;

FIG. 5 is a plan view schematically illustrating the conductive layer of FIG. 4 and pixel electrodes positioned over the conductive layer;

FIG. 6 is an enlarged plan view illustrating a portion of FIG. 4;

FIGS. 7, 8, 9 and 10 are diagrams for describing effects of the disclosure;

FIG. 11 is a plan view schematically illustrating a portion of a display panel according to an embodiment of the disclosure;

FIG. 12 is a plan view schematically illustrating a portion of a display panel according to an embodiment of the disclosure;

FIG. 13 is a plan view schematically illustrating a portion of a display panel according to an embodiment of the disclosure;

FIG. 14 is a plan view schematically illustrating a portion of a display panel according to an embodiment of the disclosure;

FIG. 15 is a cross-sectional view schematically illustrating a cross section of the conductive layer taken along line A-A′ of FIG. 6;

FIG. 16 is a cross-sectional view schematically illustrating a portion of a display panel according to an embodiment of the disclosure;

FIG. 17 is a perspective view illustrating an electronic apparatus according to an embodiment of the disclosure;

FIG. 18 is an exploded perspective view of the electronic apparatus of FIG. 17; and

FIG. 19 is a block diagram schematically illustrating the electronic apparatus of FIG. 17.

### DETAILED DESCRIPTION OF THE EMBODIMENTS

Detailed reference will now be made to the embodiments, examples of which are illustrated in the accompanying drawings, where like reference numerals indicate like elements throughout. It should be understood that the present embodiments may take various forms and are not limited to the descriptions provided herein. Accordingly, the embodiments are described below with reference to the figures to explain aspects of the present disclosure. As used herein, the term “and/or” includes any and all combinations of one or more of the listed items. Throughout the disclosure, the expression “at least one of a, b, or c” indicates only a, only b, only c, both a and b, both a and c, both b and c, all of a, b, and c, or variations thereof.

The disclosure permits various modifications and encompasses numerous embodiments. Certain embodiments are illustrated in the accompanying drawings and described in detail in this written description. The effects and features of the disclosure, as well as methods for achieving them, will be described in greater detail with reference to the accompanying drawings, which depict specific embodiments. This disclosure may, however, be embodied in many different forms and should not be construed as limited to the embodiments set forth herein.

One or more embodiments will be described below in more detail with reference to the accompanying drawings. Components that are identical or correspond to each other are assigned the same reference numerals across all figures, and redundant descriptions are omitted.

It will be understood that when a component, such as a layer, a film, a region, or a plate, is referred to as being “on” another component, the component can be directly on the other component or intervening components may be present thereon. Sizes of elements in the drawings may be exaggerated or reduced for convenience of description. In other words, since sizes and thicknesses of components in the drawings are arbitrarily illustrated for convenience of explanation, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In an embodiment below, terms such as “first” and “second” are used herein merely to describe a variety of elements, but the elements are not limited by the terms. Such terms are used for the purpose of distinguishing one element from another element.

In an embodiment below, it will be further understood that the terms “comprises” and/or “comprising” used herein specify the presence of stated features or components, but do not preclude the presence or addition of one or more other features or components.

“A and/or B” as used herein may include “A,” “B,” or “A and B.” In addition, “at least one of A and B” may include “A,” “B,” or “A and B.”

It will be understood that when a layer, region, or component is referred to as being “connected” to another layer, region, or component, it may be “directly connected” to the other layer, region, or component or may be “indirectly connected” to the other layer, region, or component with other layer, region, or component therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component therebetween.

The present disclosure focuses on a display panel with a unique design for reducing the intensity of reflected light caused by external illumination. It achieves this by incorporating a plurality of conductive lines (such as driving voltage and data lines) with wave-shaped portions in the open areas of a pixel-defining layer (PDL). These wave shapes prevent strong luminance reflections resulting from diffraction, enhancing image visibility and supporting high-resolution display quality even under bright ambient light conditions.

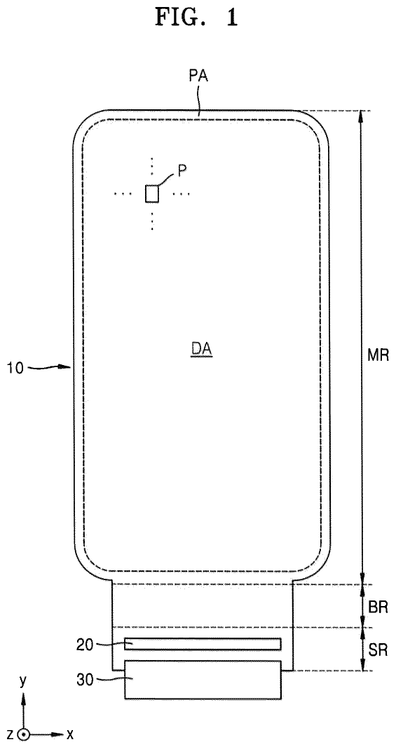

FIG. 1 is a plan view schematically illustrating a portion of a display panel according to an embodiment of the disclosure.

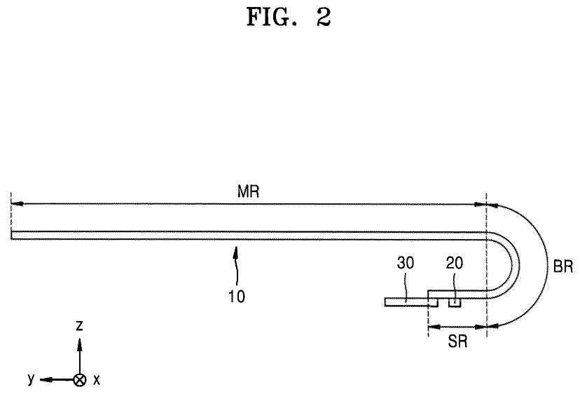

FIG. 1 is a plan view schematically illustrating a display panel 10 according to an embodiment, and FIG. 2 is a lateral view schematically illustrating the display panel 10 of FIG. 1. The display panel 10 according to the present embodiment has a bent portion as shown in FIG. 2, but for convenience of description, the display panel 10 is shown unbent in FIG. 1.

However, one or more embodiments are not limited thereto, and any electronic apparatus that includes a display panel may fall within the scope of the disclosure. Such electronic apparatus is an apparatus for displaying moving images or still images, and may be a portable electronic apparatus, such as a display device, a mobile phone, a smartphone, a tablet personal computer (PC), a mobile communication terminal, an electronic notebook, an electronic book, a portable multimedia player (PMP), a navigation device, or an ultra-mobile PC (UMPC). Alternatively, the electronic apparatus may be a television, a laptop, a monitor, a billboard, or Internet of things (IOT), which may display moving images or still images. Alternatively, the electronic apparatus may be a wearable device, such as a smart watch, a watch phone, a glasses-type display, or a head-mounted display (HMD). In addition, the electronic apparatus may be an instrument panel for a vehicle, a center information display (CID) disposed on a center fascia or dashboard of a vehicle, a rearview mirror display replacing side-view mirrors of a vehicle, or a display device disposed on the rear surface of a front seat for the entertainment of passengers in the backseat of a vehicle.

The display panel 10 may include a display area DA and a peripheral area PA outside the display area DA. The display area DA is a portion for displaying images, and a plurality of pixels may be disposed in the display area DA. When viewed from a direction approximately perpendicular to the display panel 10, the display area DA may have various shapes such as a circular shape, an elliptical shape, a polygonal shape, and a shape of a particular figure. FIG. 1 shows the display area DA having an approximately rectangular shape with rounded corners. The peripheral area PA may be positioned outside the display area DA.

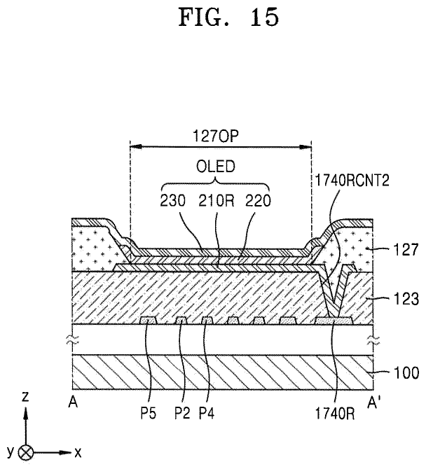

Because the display panel 10 includes a substrate 100 (see FIG. 15), it may also be understood that the substrate 100 includes the display area DA and the peripheral area PA. Various elements included in the display panel 10 may be positioned on the substrate 100. The substrate 100 may include glass, metal, or polymer resin. When the display panel 10 is bent in a bending area BR, as described below, the substrate 100 has flexible or bendable properties. In this case, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the substrate 100 may have a multi-layered structure including two layers and a barrier layer therebetween, wherein the two layers each include the polymer resin described above, and the barrier layer includes an inorganic material (e.g., silicon oxide, silicon nitride, or silicon oxynitride).

A plurality of pixels P may be positioned in the display area DA. Each of the pixels P may refer to a sub-pixel and may include a display element, such as an organic light-emitting diode (OLED). For example, the pixel P may emit red, green, blue, or white light.

The display panel 10 may also have a main area MR, the bending area BR, and a sub-area SR, wherein the bending area BR is outside the main area MR, and the sub-area SR is positioned on the opposite side of the main area MR relative to the bending area BR. The display panel 10 is bent in the bending area BR, as shown in FIG. 2, so that at least a portion of the sub-area SR overlaps the main area MA when viewed from the z-axis direction. However, the disclosure is not limited to the bendable display panel 10 and an electronic apparatus having the display panel 10, and may be applicable to display panels that are not bendable. The sub-area SR may be a non-display area. Because the display panel 10 is bent in the bending area BR, when the display device is viewed from the front (toward a −z direction), the non-display area may not be visible, or even when the non-display area is visible, the visible area may be reduced.

A driving chip 20 may be disposed in the sub-area SR of the display panel 10. The driving chip 20 may include an integrated circuit for driving the display panel 10. The integrated circuit may be a data driving integrated circuit for generating data signals, but one or more embodiments are not limited thereto.

The driving chip 20 may be mounted on the sub-area SR of the display panel 10. The driving chip 20 is mounted on the same surface as a display surface of the driving chip 20, but as the display panel 10 is bent in the bending area BR as described above, the driving chip 20 may be positioned on a rear surface of the main area MA.

A printed circuit board 30 or the like may be attached to an end of the sub-area SR of the display panel 10. The printed circuit board 30 or the like may be electrically connected to the driving chip 20 through a pad on the substrate 100.

Hereinbelow, an organic light-emitting display panel is described as an example of the display panel 10 according to an embodiment. However, the display panel of the disclosure is not limited thereto. In another embodiment, the display panel of the disclosure may be, for example, an inorganic light-emitting display panel (or an inorganic electroluminescent (EL) display panel) or a quantum dot light-emitting display panel. For example, an emission layer of a display element included in the display panel may include an organic material or an inorganic material. In addition, the display panel may have an emission layer and quantum dots positioned on a path of light emitted from the emission layer.

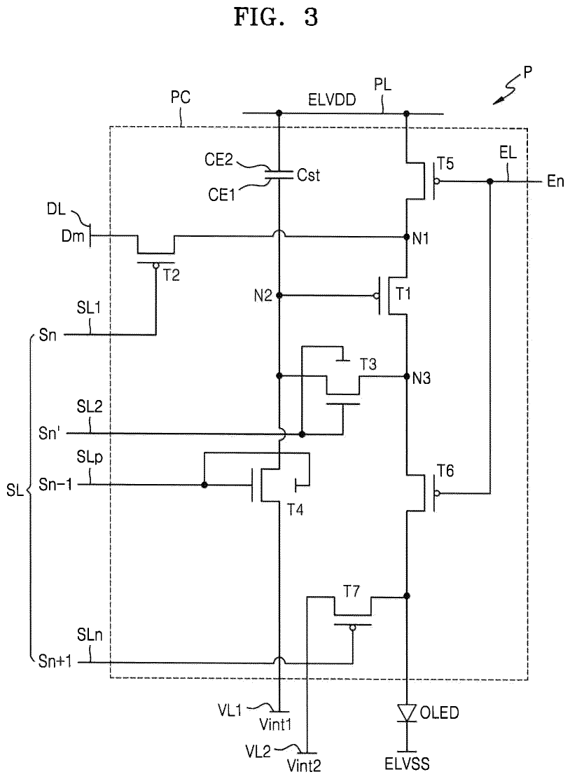

FIG. 3 is an equivalent circuit diagram of a pixel included in the display panel 10 of FIG. 1. As shown in FIG. 3, the pixel P may include a pixel circuit PC and an organic light-emitting diode OLED electrically connected to the pixel circuit PC.

The pixel circuit PC may include a plurality of thin-film transistors T1 to T7 and a storage capacitor Cst, as shown in FIG. 3. The plurality of thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least one of the lines, e.g., the driving voltage line PL, may be shared among neighboring pixels P.

The plurality of thin-film transistors T1 to T7 may include a driving transistor T1, a write transistor T2, a compensation transistor T3, a first initialization transistor T4, an operation control transistor T5, an emission control transistor T6, and a second initialization transistor T7.

The organic light-emitting diode OLED may include a pixel electrode and an opposite electrode. The pixel electrode of the organic light-emitting diode OLED may be connected to the driving transistor T1 via the emission control transistor T6 and may receive a driving current, and the opposite electrode may receive a common voltage ELVSS. The organic light-emitting diode OLED may generate light of a luminance corresponding to the driving current.

Some of the plurality of thin-film transistors T1 to T7 may be n-channel metal-oxide-semiconductor field-effect transistors (MOSFETs; NMOSs), and the remaining thin-film transistors may be p-channel MOSFETs (PMOSs). For example, the compensation transistor T3 and the first initialization transistor T4 among the plurality of thin-film transistors T1 to T7 may be NMOSs, and the remaining thin-film transistors may be PMOSs. Alternatively, the compensation transistor T3, the first initialization transistor T4, and the second initialization transistor T7 among the plurality of thin-film transistors T1 to T7 may be NMOSs, and the remaining thin film transistors may be PMOSs. Alternatively, the plurality of thin-film transistors T1 to T7 may all be NMOSs or PMOSs. The plurality of thin-film transistors T1 to T7 may include amorphous silicon or polysilicon. If necessary, an NMOS thin-film transistor may include an oxide semiconductor. Hereinbelow, for convenience, a case is described in which the compensation transistor T3 and the first initialization transistor T4 are NMOSs including an oxide semiconductor, and the remaining thin film transistors are PMOSs.

The signal lines may include a first scan line SL1 for transmitting a first scan signal Sn, a second scan line SL2 for transmitting a second scan signal Sn′, a previous scan line SLp for transmitting a previous scan signal Sn−1 to the first initialization transistor T4, a next scan line SLn for transmitting a next scan signal Sn+1 to the second initialization transistor T7, an emission control line EL for transmitting an emission control signal En to the operation control transistor T5 and the emission control transistor T6, and a data line DL crossing the first scan line SL1 and transmitting a data signal Dm.

The driving voltage line PL may transmit a driving voltage ELVDD to the driving transistor T1, the first initialization voltage line VL1 may transmit a first initialization voltage Vint1 for initializing the driving transistor T1, and the second initialization voltage line VL2 may transmit a second initialization voltage Vint2 for initializing the pixel electrode of the organic light-emitting diode OLED.

A driving gate electrode of the driving transistor T1 may be connected to the storage capacitor Cst through a second node N2. Either one of a source region or a drain region of the driving transistor T1 may be connected to the driving voltage line PL via a first node N1 and the operation control transistor T5, and the other one of the source region and the drain region of the driving transistor T1 may be electrically connected to the pixel electrode of the operation control transistor T5 via a third node N3 and the emission control transistor T6. The driving transistor T1 may receive the data signal Dm through the operation of the write transistor T2 and supply a driving current to the organic light-emitting diode OLED.

A switching gate electrode of the write transistor T2 may be connected to the first scan line SL1 for transmitting the first scan signal Sn. Either one of a source region or a drain region of the write transistor T2 may be connected to the data line DL, and the other one of the source region and the drain region of the write transistor T2 may be connected to the driving voltage line PL via the operation control transistor T5 while being connected to the driving transistor T1 via the first node N1. The write transistor T2 may be turned on in response to the first scan signal Sn received through the first scan line SL1 and may transfer the data signal from the data line DL to the driving transistor T1 through the first node N1.

A compensation gate electrode of the compensation transistor T3 may be connected to the second scan line SL2. Either one of a source region or a drain region of the compensation transistor T3 may be connected to the pixel electrode of the organic light-emitting diode OLED via the third node N3 and the emission control transistor T6. The other one of the source region and the drain region of the compensation transistor T3 may be connected via the second node N2 to a first capacitor electrode CE1 of the storage capacitor Cst and the driving gate electrode of the driving transistor T1. The compensation transistor T3 may be turned on in response to the second scan signal Sn′ received via the second scan line SL2, and may diode-connect the driving transistor T1.

A first initialization gate electrode of the first initialization transistor T4 may be connected to the previous scan line SLp. Either one of the source region or the drain region of the first initialization transistor T4 may be connected to the first initialization voltage line VL1. The other one of the source region and the drain region of the first initialization transistor T4 may be connected via the second node N2 to the first capacitor electrode CE1 of the storage capacitor Cst and the driving gate electrode of the driving transistor T1. The first initialization transistor T4 may be turned on in response to the previous scan signal Sn−1 received via the previous scan line SLp and may initialize a voltage of the driving gate electrode of the driving transistor T1 by transferring the first initialization voltage Vint1 to the driving gate electrode of the driving transistor T1.

An operation control gate electrode of the operation control transistor T5 may be connected to the emission control line EL. Either one of a source region or a drain region of the operation control transistor T5 may be connected to the driving voltage line PL, and the other one of the source region or the drain region of the operation control transistor T5 may be connected to the driving transistor T1 and the write transistor T2 via the first node N1.

An emission control gate electrode of the emission control transistor T6 may be connected to the emission control line EL. Either one of a source region and a drain region of the emission control transistor T6 may be connected to the driving transistor T1 and the compensation transistor T3 via the third node N3, and the other one of the source region and the drain region of the emission control transistor T6 may be electrically connected to the pixel electrode of the organic light-emitting diode OLED.

The operation control transistor T5 and the emission control transistor T6 may be simultaneously turned on in response to a signal received via the emission control line EL. This allows a driving current, resulting from the voltage difference between the voltage at the driving gate electrode of the driving transistor T1 and the driving transistor T1 itself, to flow through the organic light-emitting diode OLED.

A second initialization gate electrode of the second initialization transistor T7 may be connected to the next scan line SLn. Either one of a source region or a drain region of the second initialization transistor T7 may be connected to the pixel electrode of the organic light-emitting diode OLED, and the other one of the source region and the drain region of the second initialization transistor T7 may be connected to the second initialization voltage line VL2 to receive the second initialization voltage Vint2. The second initialization transistor T7 may be turned on in response to the next scan signal Sn+1 received via the next scan line SLn and may initialize the pixel electrode of the organic light-emitting diode OLED. The next scan line SLn and the first scan line SL1 may be the same line. In this case, the corresponding scan line may transmit the same electrical signal with a time difference and function as the first scan line SL1 or the next scan line SLn. In other words, the next scan line SLn may be a first scan line of a pixel adjacent to the pixel P shown in FIG. 3 and electrically connected to the data line DL.

The second initialization transistor T7 may be connected to the next scan line SLn, as shown in FIG. 3. However, one or more embodiments are not limited thereto, and the second initialization transistor T7 may be connected to the emission control line EL and driven in response to the emission control signal En.

The storage capacitor Cst may include the first capacitor electrode CE1 and a second capacitor electrode CE2. The first capacitor electrode CE1 of the storage capacitor Cst may be connected to the driving gate electrode of the driving transistor T1, and the second capacitor electrode CE2 of the storage capacitor Cst may be connected to the driving voltage line PL. The storage capacitor Cst may store a charge corresponding to the voltage difference between the driving gate electrode of the driving transistor T1 and the driving voltage ELVDD.

A detailed operation of each pixel P according to an embodiment is described as follows.

During an initialization period, when the previous scan signal Sn−1 is supplied via the previous scan line SLp, the first initialization transistor T4 may be turned on in response to the previous scan signal Sn−1. Consequently, the driving transistor T1 may be initialized by the first initialization voltage Vint1, which is provided via the first initialization voltage line VL1.

During a data programming period, when the first scan signal Sn and the second scan signal Sn′ are supplied via the first scan line SL1 and the second scan line SL2, the write transistor T2 and the compensation transistor T3 may be turned on in response to the first scan signal Sn and the second scan signal Sn′. In this case, the driving transistor T1 may be diode-connected by the turned-on compensation transistor T3 and forward-biased. Then, a compensation voltage (Dm+Vth, where Vth is a (−) value), which is obtained by subtracting the data signal Dm received via the data line DL by a threshold voltage (Vth) of the driving transistor T1, may be applied to the driving gate electrode of the driving transistor T1. The driving voltage ELVDD and the compensation voltage (Dm+Vth) may be applied to the two terminals of the storage capacitor Cst, respectively. A charge corresponding to the voltage difference between the voltages at the two terminals may then be stored in the storage capacitor Cst.

During an emission period, the operation control transistor T5 and the emission control transistor T6 may be turned on in response to the emission control signal En received via the emission control line EL. A driving current may be generated according to the voltage difference between the voltage of the driving gate electrode of the driving transistor T1 and the driving voltage ELVDD. This driving current may then be supplied to the organic light-emitting diode OLED via the emission control transistor T6.

As described above, some of the plurality of thin-film transistors T1 to T7 may include an oxide semiconductor. For example, the compensation transistor T3 and the first initialization transistor T4 may include an oxide semiconductor.

Polysilicon, known for its high reliability, allows precise control of the intended current flow. Therefore, when the driving transistor T1, which directly impacts the brightness of the display panel, includes a semiconductor layer made of high-reliability polysilicon, a high-resolution display panel can be achieved. On the other hand, oxide semiconductors exhibit high carrier mobility and low leakage current, resulting in minimal voltage drops even during extended operation. In other words, oxide semiconductors experience minimal color changes in images due to voltage drops, even when driven at low frequencies, making low-frequency operation feasible. Thus, when the compensation transistor T3 and the first initialization transistor T4 include the oxide semiconductor, the leakage current may be prevented from occurring, and a display panel with reduced power consumption may be implemented.

Oxide semiconductors are sensitive to light, and external light can alter the amount of current or electrical properties. To mitigate this, a metal layer may be positioned under the oxide semiconductor to absorb or reflect the external light. Accordingly, as shown in FIG. 3, each of the compensation transistor T3 and the first initialization transistor T4, which include oxide semiconductors, may feature gate electrodes located both above and below the oxide semiconductor layer. In other words, when viewed from a z-axis direction, perpendicular to the upper surface of the substrate 100, a metal layer positioned beneath the oxide semiconductor may overlap the oxide semiconductor.

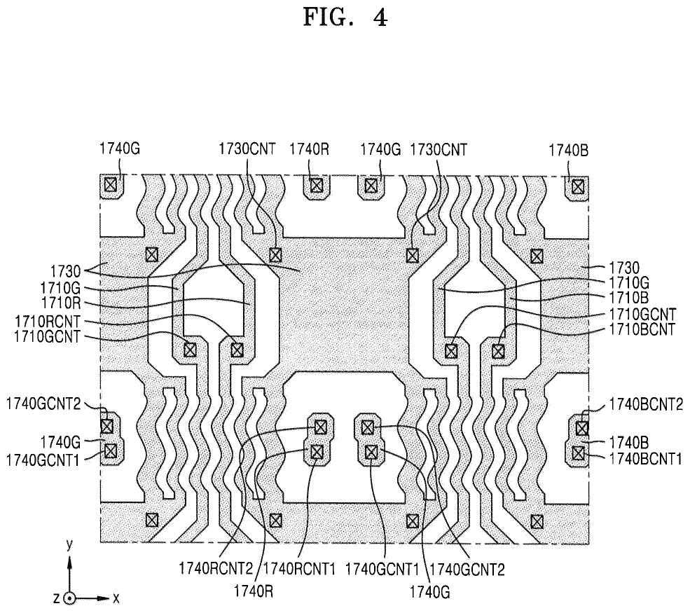

A pixel circuit, as shown in FIG. 3, with this configuration, may be formed using a plurality of conductive layers and a semiconductor layer. In addition, the pixel electrode included in the organic light-emitting element OLED may be positioned above these layers. FIG. 4 is a plan view schematically illustrating a conductive layer included in the display panel 10 of FIG. 1, and the organic light-emitting element OLED may be positioned over the conductive layer as shown in FIG. 4. As shown in FIG. 4, the conductive layer may include data lines 1710R, 1710G, and 1710B, a driving voltage line 1730, and connection lines 1740R, 1740G, and 1740B.

Each of the data lines 1710R, 1710G, and 1710B may extend approximately in a first direction (e.g., a y-axis direction). The driving voltage line 1730 may also extend approximately in the first direction (e.g., the y-axis direction).

The data lines 1710R, 1710G, and 1710B may include a red data line 1710R, a green data line 1710G, and a blue data line 1710B. Such data lines 1710R, 1710G, and 1710B may correspond to the data line DL of FIG. 3. The red data line 1710R may be electrically connected via a red contact hole 1710RCNT to a semiconductor layer positioned thereunder. This connection allows a red data signal Dm to be transferred from the red data line 1710R to the semiconductor layer and subsequently transmitted to the write transistor T2 of a red pixel circuit. The green data line 1710G may be electrically connected via a green contact hole 1710GCNT to a semiconductor layer positioned thereunder. This connection allows a green data signal Dm to be transferred from the green data line 1710G to the semiconductor layer and subsequently transmitted to the write transistor T2 of a green pixel circuit. Similarly, the blue data line 1710B may be electrically connected via a blue contact hole 1710BCNT to a semiconductor layer positioned thereunder. This connection allows a blue data signal Dm to be transferred from the blue data line 1710B to the semiconductor layer and subsequently transmitted to the write transistor T2 of a blue pixel circuit.

The driving voltage line 1730 may correspond to the driving voltage line PL of FIG. 3. The driving voltage line 1730 may be configured to apply the driving voltage ELVDD to pixels. The driving voltage line 1730 may be electrically connected to a connection line or similar structure in the underlying conductive layer through a contact hole 1730CNT. This connection facilitates the transfer of the driving voltage ELVDD to the operation control transistor T5 and a capacitor upper electrode as described above. For two pixels (two sub-pixels) adjacent to each other in a second direction (e.g., an x-axis direction), the driving voltage line 1730 may be integrally provided as one body.

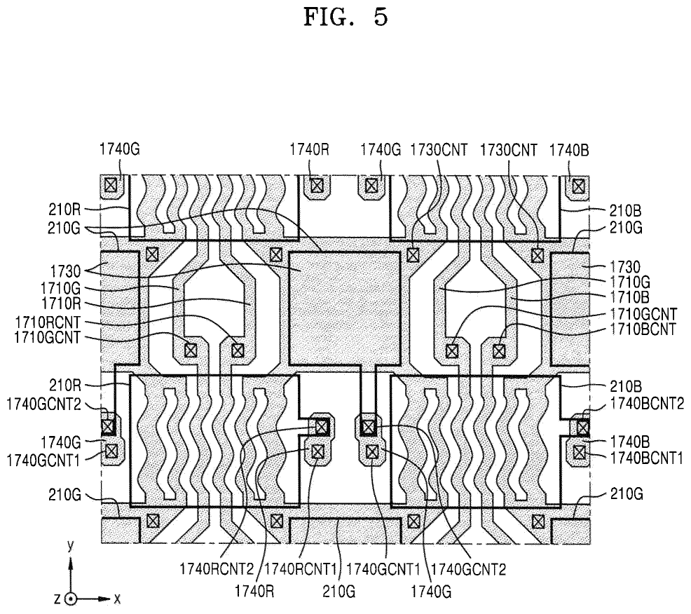

Each of the connection lines 1740R, 1740G, and 1740B may have an isolated shape. The red connection line 1740R may be electrically connected to an underlying semiconductor layer via a red contact hole 1740RCNT1, and to a pixel electrode 210R (see FIGS. 5 and 15) of the red organic light-emitting diode OLED via a red contact hole 1740RCNT2 defined in an overlying insulating layer. This configuration electrically connects the emission control transistor T6 and the pixel electrode 210R to each other, enabling a driving current from the semiconductor layer or the second initialization voltage Vint2 may be transferred to the pixel electrode 210R of the red organic light-emitting diode OLED. The green connection line 1740G may be electrically connected to an underlying semiconductor layer via a green contact hole 1740GCNT1, and to a pixel electrode 210G (see FIG. 5) of the red organic light-emitting diode OLED via a green contact hole 1740GCNT2 defined in an overlying insulating layer. This arrangement electrically connects the emission control transistor T6 and the pixel electrode 210G, allowing a driving current from the semiconductor layer or the second initialization voltage Vint2 to be transferred to the pixel electrode 210G of the green organic light-emitting diode OLED. Similarly, the blue connection line 1740B may be electrically connected to an underlying semiconductor layer via a blue contact hole 1740BCNT1, and to a pixel electrode 210B (see FIG. 5) of the blue organic light-emitting diode OLED via a blue contact hole 1740BCNT2 defined in an overlying insulating layer. This setup electrically connects the emission control transistor T6 to the pixel electrode 210B, enabling a driving current from the semiconductor layer or the second initialization voltage Vint2 to be transferred to the pixel electrode 210B of the blue organic light-emitting diode OLED.

The conductive layer may include a metal, an alloy, a conductive metal oxide, or a transparent conductive material. For example, the conductive layer shown in FIG. 4 may include silver (Ag), an Ag-containing alloy, molybdenum (Mo), a Mo-containing alloy, aluminum (Al), an Al-containing alloy, aluminum nitride (AlN), tungsten (W), tungsten nitride (Wn), copper (Cu), nickel (Ni), chrome (Cr), chrome nitride (CrN), titanium (Ti), tantalum (Ta), platinum (Pt), scandium (Sc), indium tin oxide (ITO), or indium zinc oxide (IZO). The conductive layer may have a multi-layered structure. For example, the conductive layer may have a two-layer structure of Ti/Al or a three-layer structure of Ti/Al/Ti.

FIG. 5 is a plan view schematically illustrating the conductive layer of FIG. 4 and the pixel electrodes 210R, 210G, and 210B positioned thereon. A connection relationship between the conductive layer of FIG. 4 and the pixel electrodes 210R, 210G, and 210B positioned thereon is as described above with reference to FIG. 4.

A planarization layer 123 (see FIG. 15) may be between the conductive layer of FIG. 4 and the pixel electrodes 210R, 210G, and 210B positioned thereon. The planarization layer 123 may include an organic insulating material. For example, the planarization layer 123 may include photoresist, benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or any mixtures thereof. The contact holes 1740RCNT2, 1740GCNT2, and 1740BCNT2 described above may be defined in the planarization layer 123 described above.

The pixel electrodes 210R, 210G, and 210B may be reflective electrodes. For example, the pixel electrodes 210R, 210G, and 210B may include a reflective layer including Ag, magnesium (Mg), Al, platinum (Pt), gold (Au), nickel (Ni), neodymium (Nd), iridium (Ir), chrome (Cr), and any compounds thereof, and a transparent or translucent electrode layer positioned thereon. The transparent or translucent electrode layer may have at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). For example, each of the pixel electrodes 210R, 210G, and 210B may have a three-layer structure of ITO/Ag/ITO.

A pixel-defining layer 127 (see FIG. 15) may be disposed on the planarization layer 123. The pixel-defining layer 127 may increase the distance between the respective edges of the pixel electrodes 210R, 210G, and 210B and an opposite electrode 230 (see FIG. 15) positioned above the pixel electrodes 210R, 210G, and 210B. This configuration helps prevent the occurrence of arcs or similar issues at the edges of the pixel electrodes 210R, 210G, and 210B.

The pixel-defining layer 127 may include one or more organic insulating materials selected from the group consisting of polyimide, polyamide, acrylic resin, BCB, and phenolic resin. The pixel-defining layer 127 may define openings that expose the respective centers of the pixel electrodes 210R, 210G, and 210B, and may cover edges of the pixel electrodes 210R, 210G, and 210B.

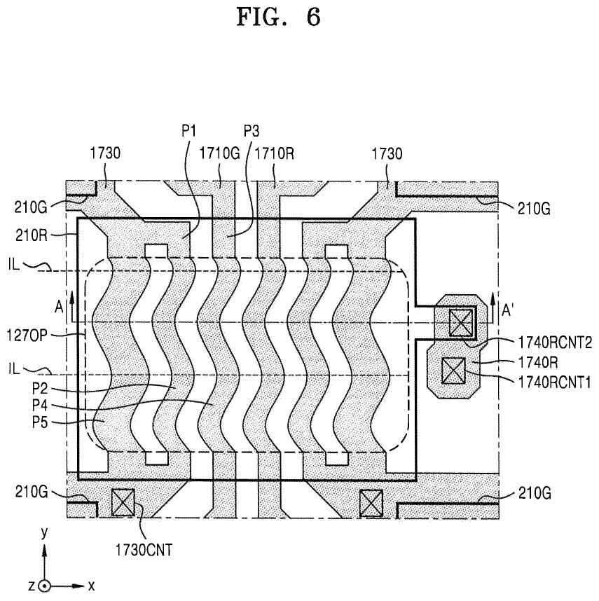

FIG. 6 is an enlarged plan view illustrating a portion of FIG. 4, and schematically shows the red pixel electrode 210R positioned in a red sub-pixel and a conductive layer thereunder. In FIG. 6, an opening 127OP in the pixel-defining layer 127, exposing the center of the red pixel electrode 210R, is indicated by dotted lines.

At least a portion of an intermediate layer 220 (see FIG. 15) of the organic light-emitting diode OLED may be positioned in the opening 127OP. The intermediate layer 220 may include an emission layer. The emission layer may include an organic material including a fluorescent or phosphorescent material emitting red, green, blue, or white light. The emission layer may be a low-molecular weight organic material or a polymer organic material, and functional layers, such as a hole transport layer (HTL), a hole injection layer (HIL), an electron transport layer (ETL), and an electron injection layer (EIL), may be selectively further disposed under and over the emission layer.

The emission layer may have a patterned shape corresponding to each of the pixel electrodes 210R, 210G, and 210B. Layers included in the intermediate layer 220 other than the emission layer may be integrally provided as a single integrated structure across the pixel electrodes 210R, 210G, and 210B. Various modifications to this configuration may also be implemented.

The opposite electrode 230 (see FIG. 15) may be a light-transmitting electrode. For example, the opposite electrode 230 may be a transparent or translucent electrode, and may include a metal thin film having a low work function, including Li, calcium (Ca), lithium fluoride (LiF), Al, Ag, Mg, and any compounds thereof. In addition, the opposite electrode 230 may further include a transparent conductive oxide (TCO) film including ITO, IZO, ZnO, or In₂O₃, over the metal thin film. The opposite electrode 230 may be integrally formed as a single integrated layer covering the entire surface of the display area DA and disposed over the intermediate layer 220 and the pixel electrodes 210R, 210G, and 210B.

The driving voltage line 1730 may include a first portion P1 and a second portion P2. The first portion P1 may overlap the red pixel electrode 210R and the pixel-defining layer 127. The second portion P2 may overlap the opening 127OP in the pixel-defining layer 127. In this case, when viewed from a direction perpendicular to the substrate 100 (z-axis direction), i.e., in a plan view, the shapes of the first portion P1 and the second portion P2 may differ. For example, as shown in FIG. 6, the shape of the first portion P1 may include a straight-line configuration extending in the y-axis direction, which aligns with the approximate extension of the driving voltage line 1730. In contrast, the shape of the second portion P2 may include a curved configuration, such as a repeating curved pattern. In FIG. 6, the second portion P2 is depicted as having a wave-like shape.

In a similar manner, each of the data lines 1710R and 1710G may include a third portion P3 and a fourth portion P4. The third portion P3 may overlap the red pixel electrode 210R and the pixel-defining layer 127. The fourth portion P4 may overlap the opening 127OP defined in the pixel-defining layer 127. In this case, when viewed from a direction perpendicular to the substrate 100 (z-axis direction), i.e., in a plan view, the shapes of the third portion P3 and the fourth portion P4 may differ. For example, as shown in FIG. 6, the third portion P3 may have a straight-line configuration extending in the y-axis direction, corresponding to the approximate extension of the data lines 1710R and 1710G. In contrast, the fourth portion P4 may feature a curved configuration, such as a repeating curved pattern. In FIG. 6, the fourth portion P4 is illustrated with a wave-like shape.

As described above, the planarization layer 123 may be positioned on the conductive layer shown in FIG. 5, and the pixel electrodes 210R, 210G, and 210B may be positioned on the planarization layer 123. The planarization layer 123 theoretically has a flat upper surface, regardless of the shapes of the underlying elements, allowing the pixel electrodes 210R, 210G, and 210B to be formed with a flat shape. However, in practice, the upper surface of the planarization layer 123 is relatively flat compared to the steps of the elements beneath the planarization layer 123, but may not be a perfectly flat. Thus, the pixel electrodes 210R, 210G, and 210B formed on this upper surface of the planarization layer 123 may exhibit a curvature corresponding to the shapes of the elements beneath the planarization layer 123, i.e., the shape of the conductive layer illustrated in FIGS. 4 and 5.

Because the pixel electrodes 210R, 210G, and 210B are reflective electrodes, external light incident on the display panel 10 from the outside may be reflected from the upper surface of the pixel electrodes 210R, 210G, and 210B and emitted to the outside again. Accordingly, this reflected light may be visible to the user. Because the reflected light can impair the visibility of an image displayed by the display panel 10, it is important to approximately adjust the intensity or pattern of the reflected light.

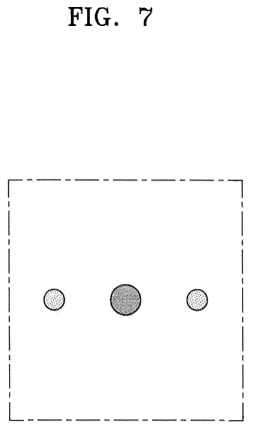

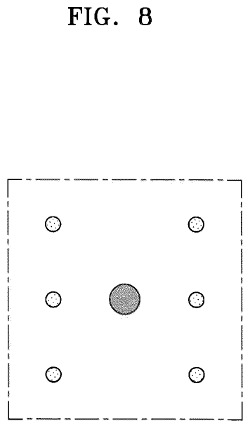

FIGS. 7 to 10 are diagrams for describing effects of the disclosure. FIG. 7 shows a case where reflected light reflected from the pixel electrodes 210R, 210G, and 210B is recognized by the viewer as three spots, and FIG. 8 shows a case where reflected light reflected from the pixel electrodes 210R, 210G, and 210B are recognized by the viewer as seven spots. In this case, an average of luminance of the three spots of FIG. 7 is greater than an average of luminance of seven spots of FIG. 8. In other words, FIG. 7 shows a case where the viewer recognizes three reflected light spots with high average luminance, and FIG. 8 shows a case where the viewer recognizes seven reflected light spots with relatively low average luminance. To enhance the visibility of an image displayed by the display panel 10, the viewer may perceive the image more clearly in the scenario illustrated in FIG. 8 compared to that in FIG. 7.

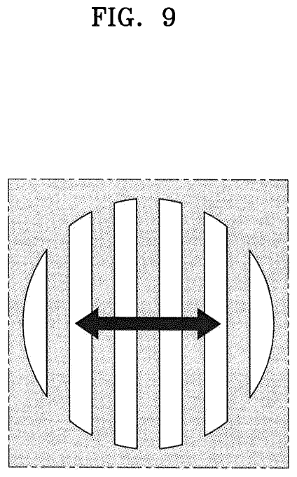

FIG. 9 shows a case where a conductive layer under a pixel electrode has a repeating straight-line pattern extending vertically and alternating in the left and right directions. An upper surface of the pixel electrode over such conductive layer may exhibit a curved surface approximately corresponding to the shape of the conductive layer thereunder, even when a planarization layer is present between the conductive layer and the pixel electrode. Accordingly, external light incident on the upper surface of the pixel electrode is reflected, producing a strong diffraction effect in the left and right directions as indicated by arrows in FIG. 9. This reflection causes three bright light spots with high average luminance to appear in the left and right directions as shown in FIG. 7.

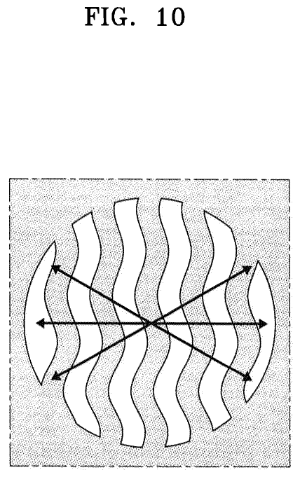

FIG. 10 shows a case where a conductive layer under a pixel electrode has a wave-shaped pattern that repeats in the left and right directions while extending approximately vertically, rather than forming a straight-line shape. An upper surface of the pixel electrode over such conductive layer may have a curved surface approximately corresponding to the shape of the conductive layer thereunder, even when a planarization layer is present between the conductive layer and the pixel electrode. External light incident on the upper surface of the pixel electrode is reflected while causing a diffraction phenomenon. However, unlike the case shown in FIG. 9, this diffraction phenomenon occurs in all directions, as indicated by the arrows of FIG. 10. Consequently, seven reflected light spots with low luminance appear as shown in FIG. 8.

As described above with reference to FIG. 6, in a plan view, the second portion P2 of the driving voltage line 1730 may be positioned in the opening 127OP in the pixel-defining layer 127. In addition, the second portion P2 may have a curved shape. For example, the second portion P2 may have a repeating curved shape. In FIG. 6, the second portion P2 is shown as having a wave shape. Similarly, in a plan view, the fourth portion P4 of each of the data lines 1710R and 1710G may be positioned in the opening 127OP in the pixel-defining layer 127. In addition, the fourth portion P4 may have a curved shape. For example, the fourth portion P4 may have a repeating curved shape. In FIG. 6, the fourth portion P4 is shown as having a wave shape. Because the portion of the conductive layer positioned in the opening 127OP in the pixel-defining layer 127 has a curved shape as shown in FIG. 10, the display panel 10 according to the present embodiment can significantly enhance image visibility for the user. This design enables the display panel to present high-resolution images, even in the presence of reflected light caused by external light sources.

The second portion P2 included in the driving voltage line 1730 may have a first convex portion protruding in a direction (+x direction) toward the closest data line 1710G, and the fourth portion P4 of the data line 1710G may have a second convex portion protruding in a direction (+x direction) away from the closest driving voltage line 1730. A first imaginary straight line IL passing through the first convex portion and perpendicular to a direction (y-axis direction) in which the driving voltage line 1730 extends may align with a second imaginary straight line IL passing through the second convex portion and perpendicular to a direction (y-axis direction) in which the data line 1710G extends, as shown in FIG. 6.

The second portion P2 included in the driving voltage line 1730 may have a plurality of first convex portions protruding in the direction (+x direction) toward the closest data line 1710G, and the fourth portion P4 of the data line 1710G may have a plurality of second convex portions protruding in the direction (+x direction) away from the closest driving voltage line 1730. Through the above, in a plan view, the second portion P2 of the driving voltage line 1730 and the fourth portion P4 of the data line 1710G, positioned in the opening 127OP in the pixel-defining layer 127, may have more curvature.

In addition, when viewed from a direction perpendicular to the substrate, the driving voltage line 1730 may further include a fifth portion P5, as shown in FIG. 6. Similar to the second portion P2, the fifth portion P5 may overlap the opening 127OP in the pixel-defining layer 127. In a plan view, the fifth portion P5 may be spaced apart from the second portion P2 in the opening 127OP in the pixel-defining layer 127, but may be connected to the first portion P1, similar to the second portion P2. In other words, the driving voltage line 1730 may branch into the second portion P2 and the fifth portion P5.

The fifth portion P5 may have a curved shape. For example, the fifth portion P5 may have a repeating curved shape. In FIG. 6, the fifth portion P5 is shown as having a wave shape. Because the a portion of the conductive layer positioned in the opening 127OP in the pixel-defining layer 127 has a curved shape as shown in FIG. 10, the display panel 10 according to the present embodiment can significantly enhance image visibility for the user. This design enables the display panel to present high-resolution images, even in the presence of reflected light caused by external light sources.

The second portion P2 included in the driving voltage line 1730 may have a first convex portion protruding in the direction (+x direction) toward the closest data line 1710G, and the fifth portion P5 of the driving voltage line 1730 may also have a third convex portion protruding in the direction (+x direction) toward the data line 1710G. The first imaginary straight line IL passing through the first convex portion and perpendicular to the direction (y-axis direction) in which the driving voltage line 1730 extends may align with a third imaginary straight line IL passing through the third convex portion and perpendicular to the direction (y-axis direction) in which the data line 1710G extends, as shown in FIG. 6.

The second portion P2 included in the driving voltage line 1730 may have a plurality of first convex portions protruding in the direction (+x direction) toward the closest data line 1710G, and the fifth portion P5 of the driving voltage line 1730 may also have a plurality of third convex portions protruding in the direction (+x direction) toward the data line 1710G. As a result, in a plan view, the second portion P2 and the fifth portion P5 of the driving voltage line 1730 positioned in the opening 127OP in the pixel-defining layer 127 may exhibit increase curvature.

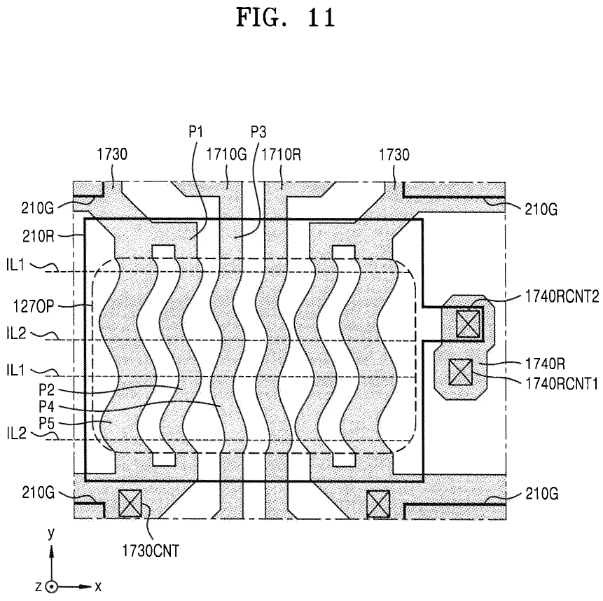

FIG. 11 is a plan view schematically illustrating a portion of the display panel 10 according to an embodiment of the present disclosure. As shown in FIG. 11, the first imaginary straight line IL1, which passes through the first convex portion of the second portion P2 of the driving voltage line 1730 and is perpendicular to the approximate y-axis direction in which the driving voltage line 1730 extends, and the second imaginary straight line IL2, which passes through the second convex portion of the fourth portion P4 of the data line 1710G and is perpendicular to the same direction, may be spaced apart. This arrangement increases the randomness of the curvature on the upper surface of the pixel electrode 210R, thereby preventing the diffraction of external incident light from being concentrated in a particular direction. In this case, a third imaginary straight line, which passes through the third convex portion of the fifth portion P5 of the driving voltage line 1730 and is perpendicular to the approximate y-axis direction, may coincide with the first imaginary straight line IL1.

The second portion P2 of the driving voltage line 1730 may have a plurality of first convex portions, and the fourth portion P4 of the data line 1710G may have a plurality of second convex portions. In this case, the first imaginary straight lines IL1 passing through the plurality of first convex portions of the second portion P2 of the driving voltage line 1730 and perpendicular to the direction (y-axis direction) in which the driving voltage line 1730 extends, and the second imaginary straight lines IL2 passing through the plurality of second convex portions of the fourth portion P4 of the data line 1710G and perpendicular to the direction (y-axis direction) in which the driving voltage line 1730 extends, may be alternately located. In this case, third imaginary straight lines passing through the third convex portions of the fifth portion P5 of the driving voltage line 1730 and perpendicular to the direction (y-axis direction) in which the driving voltage line 1730 extends may coincide with the first imaginary straight lines IL1.

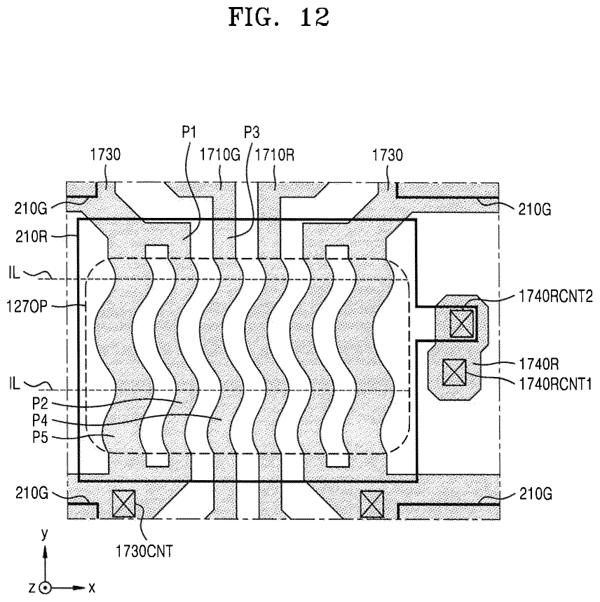

FIG. 12 is a plan view schematically illustrating a portion of the display panel 10 according to an embodiment of the present disclosure. As shown in FIG. 12, the second portion P2 included in the driving voltage line 1730 may have first convex portions protruded in the direction (+x direction) toward the closest data line 1710G, and the fourth portion P4 of the data line 1710G may have second convex portions protruded in the direction (+x direction) away from the closest driving voltage line 1730. In this case, a radius of curvature of the second portion P2 in the first convex portions and a radius of curvature of the second portion P2 between the first convex portions may be different from each other. In FIG. 12, the radius of curvature of the second portion P2 in the first convex portions is greater than the radius of curvature of the second portion P2 between the first convex portions. Similarly, a radius of curvature of the fourth portion P4 in the second convex portions and a radius of curvature of the fourth portion P4 between the second convex portions may be different from each other. In FIG. 12, the radius of curvature of the fourth portion P4 in the second convex portions is greater than the radius of curvature of the fourth portion P4 between the second convex portions.

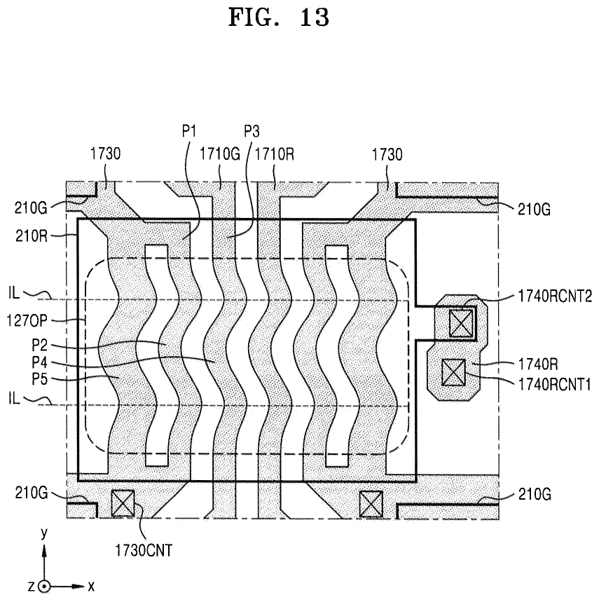

FIG. 13 is a plan view schematically illustrating a portion of the display panel 10 according to an embodiment of the present disclosure. FIG. 13 differs from FIG. 6 with respect to the position of the imaginary straight line IL. By allowing one red sub-pixel included in the display panel 10 to have the imaginary straight line IL at a position as shown in FIG. 6, and allowing another red sub-pixel to have the imaginary straight line IL at a position as shown in FIG. 13, positions of the imaginary straight lines IL throughout the display panel 10 may be different or random. As a result, the visibility of reflected light may be further reduced.

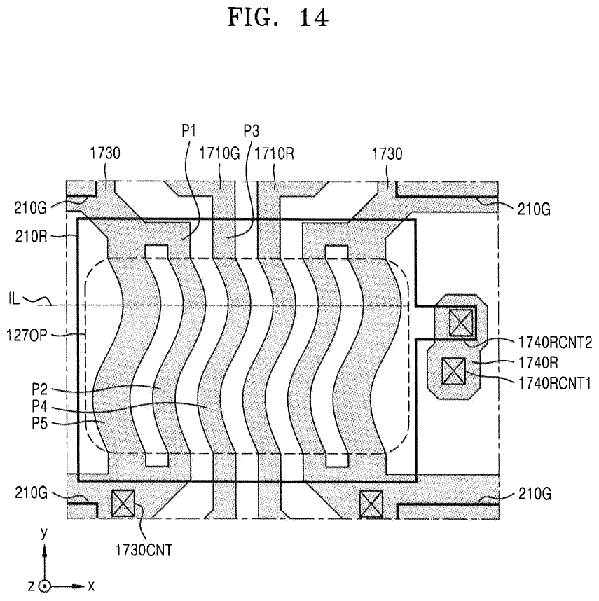

In FIGS. 6 and 13, the second portion P2 included in the driving voltage line 1730 may have two first convex portions protruded in the direction (+x direction) toward the closest data line 1710G, and the fourth portion P4 of the data line 1710G may have two second convex portions protruded in the direction (+x direction) away from the closest driving voltage line 1730. In other words, FIG. 6 shows that each of the second portion P2 and the fourth portion P4 has a wave shape similar to a sine wave that progresses in the y-axis direction. For example, each of the second portion P2 and the fourth portion P4 has a sine wave shape approximating to two cycles. However, one or more embodiments are not limited thereto. For example, as shown in FIG. 14, which is a plan view schematically illustrating a portion of the display panel 10 according to an embodiment of the present disclosure, each of the second portion P2 and the fourth portion P4 may have a sine wave shape approximating one cycle. Alternatively, each of the second portion P2 and the fourth portion P4 may have a sine wave shape of 1.5 cycle.

FIG. 15 is a cross-sectional view schematically illustrating a cross section taken along line A-A′ of FIG. 6. In FIG. 15, for convenience, the upper surface of the planarization layer 123 is completely flat. However, as described above, the upper surface of the planarization layer 123 may have a curve that roughly corresponds to a structure of a conductive layer thereunder. As a result, the pixel electrode 210R over the planarization layer 123 may also have a curved shape.

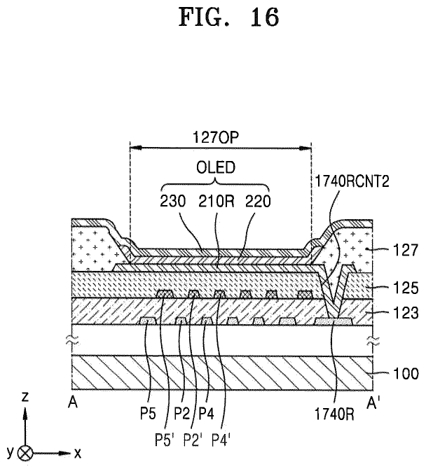

FIG. 16 is a cross-sectional view schematically illustrating a portion of the display panel 10 according to an embodiment of the present disclosure. As shown in FIG. 16, the display panel 10 according to the present embodiment may further include auxiliary lines P2′, P4′, and P5′ on layers different from layers on which the driving voltage line 1730 and the data lines 1710R, 1710G, and 1710B are disposed. FIG. 16 shows that the auxiliary lines P2′, P4′, and P5′ are positioned over the planarization layer 123, an additional planarization layer 125 covers the auxiliary lines P2′, P4′, and P5′, and the pixel electrode 210R is positioned over the additional planarization layer 125.

When viewed from a direction (z-axis direction) perpendicular to the substrate 100, the auxiliary lines P2′, P4′, and P5′ may be positioned between the driving voltage line 1730 and the data lines 1710R, 1710G, and 1710B, in the opening 127OP in the pixel-defining layer 127. Although the planarization layer 123 alleviates the step difference of the driving voltage line 1730 and the data lines 1710R, 1710G, and 1710B, as described above, the upper surface of the planarization layer 123 is not completely flat and has a slight curvature corresponding to the driving voltage line 1730 and the data lines 1710R, 1710G, and 1710B. In other words, the upper surface of the planarization layer 123 may have slightly convex portions on the driving voltage line 1730 and the data lines 1710R, 1710G, and 1710B. Additionally, portions of the upper surface of the planarization layer 123 between the driving voltage line 1730 and the data lines 1710R, 1710G, and 1710B are slightly concave. Because the auxiliary lines P2′, P4′, and P5′ are positioned at the slightly concave portions, an upper surface of the additional planarization layer 125 may have a shape that is flatter than the upper surface of the planarization layer 123. Thus, the pixel electrode 210R may also have a flatter shape. These auxiliary lines P2′, P4′, and P5′ may have an island shape, which is electrically isolated, and thus, electrical signals may not be applied thereto.

Although the red pixel electrode 210R is mainly described above, one or more embodiments are not limited thereto. For example, as shown in FIG. 5, the above-described content related to the red pixel electrode 210R may also apply to the blue pixel electrode 210B, which is similarly positioned on the driving voltage line 1730 and the data lines 1710G and 1710. Additionally, in a plan view, the green pixel electrode 210G may be positioned within a wider portion of the driving voltage line 1730, as shown in FIG. 6. In this case, the green pixel electrode 210G is formed flat, thereby preventing the presentation of strongly visible reflected light caused by diffraction in the green sub-pixel.

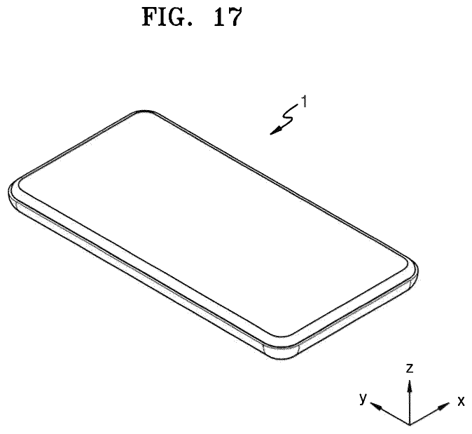

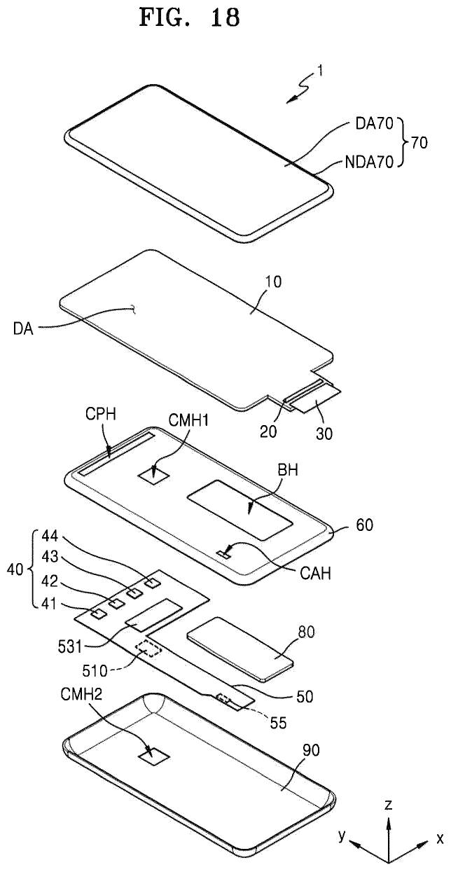

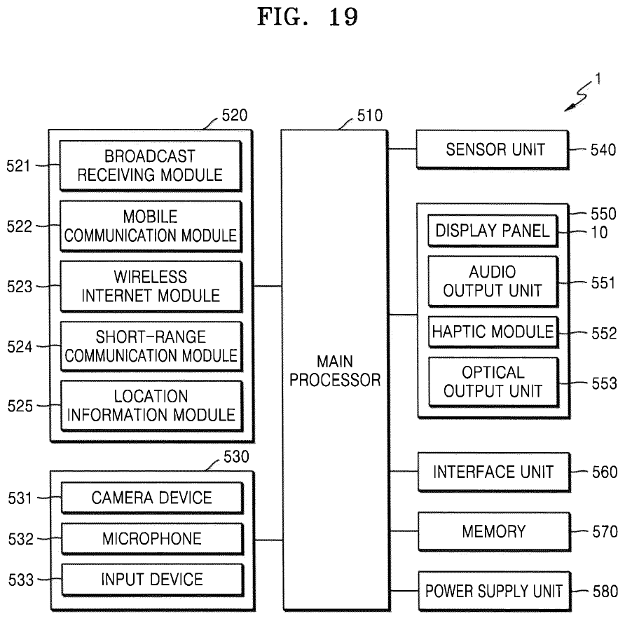

Although the display panel 10 is described above, one or more embodiments are not limited thereto, and any electronic apparatus including such a display panel 10 is within the scope of the disclosure. For example, FIG. 17 is a perspective view illustrating an electronic apparatus 1 according to an embodiment, FIG. 18 is an exploded perspective view of the electronic apparatus 1, and FIG. 19 is a block diagram schematically illustrating the electronic apparatus 1.

Referring to FIGS. 1 and 2, the electronic apparatus 1 according to an embodiment is an apparatus for displaying moving images or still images, and may be not only a portable electronic apparatus, such as mobile phones, smartphones, tablet personal computers (PCs), mobile communication terminals, electronic books, portable multimedia players (PMPs), navigations, or ultra mobile PCs (UMPCs), but also various products such as televisions, laptop computers, monitors, billboards, and Internet of things (IoT). The electronic apparatus 1 according to an embodiment may also be used for wearable devices, such as smart watches, watch phones, glasses-type displays, and head-mounted displays (HMDs). The electronic apparatus 1 according to an embodiment may be used as an instrument panel for a vehicle, a center information display (CID) disposed on a center fascia or a dashboard, a rearview mirror display replacing side-view mirrors of a vehicle, and/or a display disposed on the rear surface of a front seat for an entertainment for passengers in the backseat of a vehicle.

In FIGS. 1 and 2, for convenience of description, the electronic apparatus 1 according to an embodiment is used for a smartphone. The electronic apparatus 1 according to an embodiment may include a cover window 70, the display panel 10, a data driver 20, a display circuit board 30, a component 40, a main circuit board 50, a bracket 60, a battery 80, and a lower cover 90.

In a plan view, “left,” “right” “up,” and “down” as used herein refer to directions when the display panel 10 is viewed from a direction perpendicular to the display panel 10. For example, “left” refers to a −x direction, “right” refers to a +x direction, “up” refers to a +y direction, and “down” refers to a −y direction.

In a plan view, the electronic apparatus 1 may have a rectangular shape. For example, the electronic apparatus 1 may have a rectangular planar shape having a short side in the x direction and a long side in the y direction, as shown in FIG. 1. A corner where the short side in the x direction meets the long side in the y direction may be rounded with a certain curvature, or formed as a right angle. A planar shape of the electronic apparatus 1 is not limited to a rectangle, and may be formed into other polygonal, elliptical, or irregular shapes.

The cover window 70 may be disposed over the display panel 10 to cover an upper surface of the display panel 10. As a result, the cover window 70 may protect the upper surface of the display panel 10.

The cover window 70 may include a transmissive cover unit DA70 corresponding to the display panel 10 and a light-shielding cover unit NDA70 surrounding the transmissive cover unit DA70. The light-shielding cover unit NDA70 may include an opaque material (e.g., a colored opaque material) that blocks light. The light-shielding cover unit NDA70 may include a pattern that may be shown to a user when an image is not displayed.

The display panel 10 may be disposed under the cover window 70. The display panel 10 may overlap the transmissive cover unit DA70 of the cover window 70.

The display panel 10 may include the display area DA. The display area DA is an area on which an image is displayed, and the display area DA may include an area (hereinafter referred to as “component area”) that transmits light or signals emitted from the component 40 disposed under the display panel 10. The component 40 may include sensors and cameras that use visible light, infrared light, or sound.

The display panel 10 may be a light-emitting display panel including a light-emitting diode. The light-emitting diode may include an organic light-emitting diode including an organic emission layer. In some embodiments, the light-emitting diode may be an inorganic light-emitting diode including an inorganic material. The inorganic light-emitting diode may include a PN diode including inorganic semiconductor-based materials. When a voltage is applied to a PN junction diode in the forward direction, holes and electrons may be injected, and energy generated by recombination of the holes and the electrons may be converted into light energy so that light of a certain color may be emitted. The inorganic light-emitting diode described above may have a width of several to several hundreds of micrometers, and in some embodiments, the inorganic light-emitting diode may be referred to as a micro light-emitting diode (LED).

The display panel 10 may be a rigid display panel that is not easily bendable due to the rigidity thereof, or a flexible display panel that is easily bendable, foldable, or rollable due to the flexibility thereof. For example, the display panel 10 may be a foldable display panel, a curved display panel having a bendable display surface, a bended display panel in which an area other than the display surface is bendable, a rollable display panel, or a stretchable display panel.

The display panel 10 may be a transparent display panel in which an object or a background disposed on a lower surface of the display panel 10 is visible through the upper surface of the display panel 10. Alternatively, the display panel 10 may be a reflective display panel in which an object or a background may be reflected from the upper surface of the display panel 10.

The data driver 20 may be mounted on the display panel 10 in the form of an integrated circuit (IC). In another embodiment, the data driver 20 may be disposed on the display circuit board 30.

The display circuit board 30 may be attached to one side of the display panel 10. The display circuit board 30 may be a flexible printed circuit board (FPCB) that is bendable, a rigid printed circuit board (PCB) that is hard and does not bend easily, or a composite printed circuit board including both the PCB and the FPCB.

In an embodiment, a touch sensor driving unit may be disposed on the display circuit board 30. The touch sensor driving unit may be formed as an IC. The touch sensor driving unit may be attached to the display circuit board 30. The touch sensor driving unit may be electrically connected to touch electrodes of a touch screen layer of the display panel 10 through the display circuit board 30.

The touch screen layer of the display panel 10 may detect a touch input of a user by using at least one of various touch methods such as a resistive film method and an electrostatic capacitance method. For example, when the touch screen layer of the display panel 10 detects the user's touch input by using the electrostatic capacitance method, the touch sensor driving unit may apply driving signals to driving electrodes of the touch electrodes and detect voltages charged in mutual capacitances between the driving electrodes and sensing electrodes. This allows the system to determine whether the user has touched the screen. The user's touch may include a contact touch and a proximity touch. The contact touch refers to an object, such as a user's finger or a pen, directly touching the cover window 70 disposed on the touch screen layer. The proximity touch refers to an object, such as a user's finger or a pen, being positioned close to the cover window 70, such as hovering. The touch sensor driving unit may transmit sensor data to a main processor 510 according to the detected voltages, and the main processor 510 may analyze the sensor data to calculate touch coordinates on which a touch input has occurred.

A control unit for supplying driving voltages for driving pixels, a gate driver, and the data driver 20 of the display panel 10 may be disposed on the display circuit board 30.

The bracket 60 for supporting the display panel 10 may be disposed under the display panel 10. The bracket 60 may include plastic, metal, or both plastic and metal. A first camera hole CMH1 into which a camera device 531 is inserted, a battery hole BH in which the battery 80 is disposed, a cable hole CAH through which a cable connected to the display circuit board 30 passes may be provided in the bracket 60. A component hole CPH overlapping the display panel 10 may be provided in the bracket 60. The component hole CPH may overlap the components 40 of the main circuit board 50 in the third direction (z direction). In an embodiment, the display area DA of the display panel 10 may overlap the components 40 of the main circuit board 50 in the third direction (z direction). In another embodiment, the component hole CPH may not be provided in the bracket 60.

In an embodiment, the component 40 may include first to fourth components 41, 42, 43, and 44 overlapping the display panel 10. Each of the first to fourth components 41, 42, 43, and 44 may be provided as a proximity sensor, an illumination sensor, an iris sensor, a face recognition sensor, and a camera (or image sensor). The proximity sensor using infrared light may detect an object disposed close to the upper surface of the electronic apparatus 1, and the illumination sensor may detect a brightness of light incident on the upper surface of the electronic apparatus 1. In addition, the iris sensor may photograph a person's iris positioned above the upper surface of the electronic apparatus 1, and the camera may photograph an object positioned above the upper surface of the electronic apparatus 1. The component 40 is not limited to the proximity sensor, the illumination sensor, the iris sensor, the face recognition sensor, and the camera, and may include various sensors described below.

The main circuit board 50 and the battery 80 may be disposed under the bracket 60. The main circuit board 50 may be a PCB or a FPCB.

The main circuit board 50 may include the main processor 510, the camera device 531, a main connector 55, and the components 40. The main processor 510 may be formed as an IC. The camera device 531 may be disposed on both the upper surface and the lower surface of the main circuit board 50, and each of the main processor 510 and the main connector 55 may be disposed on either the upper surface or the lower surface of the main circuit board 50.

The main processor 510 may control all functions of the electronic apparatus 1. For example, the main processor 510 may output digital video data to the data driver 20 through the display circuit board 30 so that an image is displayed on the display panel 10. The main processor 510 may receive sensing data from the touch sensor driving unit. The main processor 510 may determine whether the user has touched, according to the sensing data, and execute an operation corresponding to the direct touch or the proximity touch of the user. The main processor 510 may be an application processor, a central processing unit, or a system chip, which include an IC.

The camera device 531 may process an image frame, such as a still image or a moving image, obtained by an image sensor in a camera mode, and output the processed image frame to the main processor 510. The camera device 531 may include at least one of a camera sensor (e.g., a charge-coupled device (CCD), a complementary metal-oxide-semiconductor (CMOS), or the like), a photo sensor (or image sensor), and a laser sensor. The camera device 531 may be connected to the image sensor, from among the components, overlapping the display area DA, and may process images input to the image sensor.

A cable that has passed through the cable hole CAH provided in the bracket 60 may be connected to the main connector 55, so that the main connector 55 may be electrically connected to the display circuit board 30.

The main circuit board 50 may further include a wireless communication unit 520, an input unit 530, a sensor unit 540, an output unit 550, an interface unit 560, a memory 570, and/or a power supply unit 580 shown in FIG. 19, in addition to the main processor 510, the camera device 531, and the main connector 55.

The wireless communication unit 520 may include at least one of a broadcast receiving module 521, a mobile communication module 522, a wireless Internet module 523, a short-range communication module 524, and a location information module 525.

The broadcast receiving module 521 may receive broadcast signals and/or broadcast-related information from an external broadcast management server through a broadcast channel. The broadcast channel may include satellite channels and terrestrial channels.

The mobile communication module 522 may transmit and receive wireless signals to and from at least one of a base station, an external terminal, and a server on a mobile communication network established according to technical standards or communication schemes for mobile communication (e.g., Global System for Mobile communication (GSM), Code Division Multiple Access (CDMA), Code Division Multiple Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and Long Term Evolution-Advanced (LTE-A)). The wireless signals may include various forms of data including voice call signals, video call signals, or text/multimedia message transmissions and receptions.

The wireless Internet module 523 refers to a module for accessing the wireless Internet. The wireless Internet module 523 may be configured to transmit and receive wireless signals on a communication network according to wireless Internet technologies. The wireless Internet technologies may include, for example, Wireless LAN (WLAN), Wireless-Fidelity (Wi-Fi), Wi-Fi Direct, and Digital Living Network Alliance (DLNA).

The short-range communication module 524 is for short range communication and may support short-range communication by using at least one of Bluetooth™, Radio Frequency Identification (RFID), Infrared Data Association (IrDA), Ultra Wideband (UWB), ZigBee, Near Field Communication (NFC), Wi-Fi, Wi-Fi Direct, and Wireless Universal Serial Bus (Wireless USB). The short-range communication module 524 may support, through a short-range wireless communication network (Wireless Area Networks), wireless communication between the electronic apparatus 1 and a wireless communication system, between the electronic apparatus 1 and another electronic device, or between the electronic apparatus 1 and a network where the other electronic device (or external server) is positioned. The short-range wireless communication network may be a short-range wireless personal communication network (e.g., Wireless Personal Area Networks). The other electronic device may be a wearable device capable of mutually exchanging (or linking) data with the electronic apparatus 1.

The location information module 525 is a module for obtaining a location (or current location) of the electronic apparatus 1 and may include a Global Positioning System (GPS) module or a Wi-Fi module.

The input unit 530 may include an image input unit for receiving image signals, such as the camera device 531, an audio input unit for receiving audio signals, such as a microphone 532, and an input device 533 for receiving information from a user.

The camera device 531 may process image frames, such as still images or moving images, obtained by an image sensor in a video call mode or a photographing mode. The processed image frame may be displayed on the display panel 10 or stored in the memory 570.

The microphone 532 may process external audio signals into electrical speech data. The processed speech data may be variously used depending on the function being performed (or application running) in the electronic apparatus 1.

The main processor 510 may control operations of the electronic apparatus 1 to correspond to information received through the input device 533. The input device 533 may include a mechanical input means or a touch input means, such as a button, a dome switch, a jog wheel, or a jog switch, positioned on the rear surface or the side surface of the electronic apparatus 1. The touch input means may include a touch screen layer of the display panel 10.

The sensor unit 540 may include one or more sensors that sense at least one of information within the electronic apparatus 1, information about a surrounding environment of the electronic apparatus 1, and user information, and generate a sensing signal corresponding thereto. Based on the sensing signal described above, the main processor 510 may control driving or operation of the electronic apparatus 1 or perform data processing, functions, or operations related to applications installed on the electronic apparatus 1. The sensor unit 540 may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environment sensor (e.g., a barometer, a hygrometer, a thermometer, a radiation detection sensor, a heat detection sensor, a gas detection sensor, or the like), and a chemical sensor (e.g., an electronic nose, a healthcare sensor, a biometric recognition sensor, or the like).

The output unit 550 aims to generate an output related to vision, hearing, or tactile sensations, and may include at least one of the display panel 10, an audio output unit 551, a haptic module 552, and an optical output unit 553.

The display panel 10 may display (or output) information processed in the electronic apparatus 1. For example, the display panel 10 may display execution screen information of an application running in the electronic apparatus 1, a user interface (UI) according to the execution screen information, or graphic user interface (GUI) information. The display panel 10 may include a display layer for displaying images and a touch screen layer for detecting a touch input of a user. As a result, the display panel 10 may function as one of the input devices 533 that provide an input interface between the electronic apparatus 1 and the user, and at the same time, may function as one of the output units 550 that provide an output interface between the electronic apparatus 1 and the user.

The audio output unit 551 may output audio data received from the wireless communication unit 520 or stored in the memory 570, in a call signal reception mode, a call mode, a recording mode, a speech recognition mode, or a broadcast reception mode. The audio output unit 551 may also output audio signals related to functions (e.g., call signal reception sound and message reception sound) performed in the electronic apparatus 1. The audio output unit 551 may include a receiver and a speaker. At least one of the receiver and the speaker may be an audio generation device that is attached to a lower portion of the display panel 10 to vibrate the display panel 10 and output sound. The audio generation device may be a piezoelectric element or a piezoelectric actuator that contracts and expands in response to an electric signal, or may be an exciter that generates magnetic force by using a voice coil and vibrates the display panel 10.

The haptic module 552 may generate various tactile effects that may be felt by the user. The haptic module 552 may provide vibration to the user as a tactile effect. The haptic module 552 may provide tactile feedback not only through direct contact but also by stimulating the user's muscle senses in their fingers or arms, allowing them to perceive the tactile effect.

The optical output unit 553 may output a signal for notifying the occurrence of an event by using light from a light source. Examples of the events occurring in the electronic apparatus 1 may include receiving a message, receiving a call signal, receiving a missed call, an alarm, a schedule reminder, receiving an e-mail, and receiving information through an application. A signal output from the optical output unit 553 may be implemented as the electronic apparatus 1 emits light of one or more colors to the front or the rear. The signal output may be terminated when the electronic apparatus 1 detects the user's acknowledgement of the event.

The interface unit 560 may serve as a passage to various types of external devices connected to the electronic apparatus 1. The interface unit 560 may include at least one of a wired/wireless headset port, an external charger port, a wired/wireless data port, a memory card ort, a port for connecting a device having an identification module, an audio input/output (I/O) port, a video I/O port, and an earphone port. In response to an external device being connected to the interface unit 560, the electronic apparatus 1 may perform an appropriate control related to the connected external device.

The memory 570 may store data supporting various functions of the electronic apparatus 1. The memory 570 may store a plurality of application programs running in the electronic apparatus 1 and data and/or instructions for operating the electronic apparatus 1. At least some of the plurality of applications may be downloaded from an external server through wireless communication. The memory 570 may store applications for operations of the main processor 510, or may temporarily store input/output data, such as a phone book, messages, still images, and/or moving images. In addition, the memory 570 may store haptic data for vibration of various patterns provided to the haptic module 552, and audio data about various sounds provided to the audio output unit 551. The memory 570 may include a storage medium of at least one type among a flash memory type, a hard disk type, a solid state disk (SSD) type, a silicon disk drive (SDD) type, a multimedia card micro type, a card-type memory (e.g., Secure Digital (SD) or extreme Digital (XD) memory), random access memory (RAM), static RAM (SRAM), read-only memory (ROM), electrically erasable programmable ROM (EEPROM), programmable ROM (PROM), magnetic memory, a magnetic disk, and an optical disk.

Under the control of the main processor 510, the power supply unit 580 may receive external power and/or internal power and supply power to each of elements included in the electronic apparatus 1. The power supply unit 580 may include the battery 80. In addition, the power supply unit 580 may have a connection port, and the connection port may be configured as an example of the interface unit 560 to which an external charger is electrically connected, wherein the external charger supplies power for battery charging. Alternatively, the power supply unit 580 may be configured to charge the battery 80 wirelessly without using the connection port. The battery 80 may be disposed not to overlap the main circuit board 50 in the third direction (z direction). The battery 80 may overlap the battery hole BH provided in the bracket 60.

The lower cover 90 may constitute the exterior of the electronic apparatus 1, and may have, in the front surface thereof, an opening portion that exposes a portion of the display panel 10. The lower cover 90 may have a shape in which a surface corresponding to the display panel 10 is opened, and may be assembled in connection with the display panel 10. The lower cover 90 may be positioned on an opposite side of the window 70 with the display panel 10 therebetween. The lower cover 90 may be disposed under the main circuit board 50 and the battery 80. The lower cover 90 may be fastened and fixed to the bracket 60. The lower cover 90 may constitute the exterior of a lower surface of the electronic apparatus 1. The lower cover 90 may include plastic, metal, or both plastic and metal.

A second camera hole CMH2 through which a lower surface of the camera device 531 is exposed may be provided in the lower cover 90. A position of the camera device 531 and positions of the first and second camera holes CMH1 and CMH2 corresponding to the camera device 531 are not limited to those of the embodiment shown in FIGS. 1 and 2, and may variously modified.

According to an embodiment configured as described above, a display panel on which high-quality images may be displayed and an electronic apparatus including the display panel may be implemented. However, the scope of the disclosure is not limited to these effects.

It should be understood that embodiments described herein should be considered in a descriptive sense and not for purposes of limitation. Descriptions of features or aspects within each embodiment should be considered as available for other similar features or aspects in other embodiments. While one or more embodiments have been described with reference to the figures, it will be understood by those of ordinary skill in the art that various changes in form and details may be made therein without departing from the spirit and scope as set forth by the following claims.

What is claimed is:

1. A display panel comprising:
a substrate;
a pixel electrode disposed on the substrate;
a pixel-defining layer having an opening, wherein the pixel-defining layer covers an edge of the pixel electrode, and the opening exposes a center of the pixel electrode; and
a first line positioned between the substrate and the pixel electrode and having a first portion overlapping the pixel-defining layer and a second portion overlapping the opening, wherein, when viewed from a direction perpendicular to the substrate, a shape of the first portion differs from a shape of the second portion.

2. The display panel of claim 1, wherein, when viewed from the direction perpendicular to the substrate, the first portion is straight in a direction in which the first line extends, and the second portion is curved.

3. The display panel of claim 2, wherein, when viewed from the direction perpendicular to the substrate, the second portion is a repeating curve.

4. The display panel of claim 1, further comprising a second line positioned between the substrate and the pixel electrode and having a third portion and a fourth portion, wherein the third portion overlaps the pixel electrode and the pixel-defining layer, the fourth portion overlaps the opening, and, when viewed from the direction perpendicular to the substrate, a shape of the third portion differs from a shape of the fourth portion.

5. The display panel of claim 4, wherein, when viewed from the direction perpendicular to the substrate, each of the first portion and the third portion is straight in a direction in which the first line extends, and each of the second portion and the fourth portion is curved.

6. The display panel of claim 5, wherein, when viewed from the direction perpendicular to the substrate, each of the second portion and the fourth portion is a repeating curve.

7. The display panel of claim 5, wherein the second portion has a first convex portion protruded in a direction toward the second line, and the fourth portion has a second convex portion protruded in a direction away from the first line.

8. The display panel of claim 7, wherein a first imaginary straight line passing through the first convex portion and perpendicular to the direction in which the first line extends is spaced apart from a second imaginary straight line passing through the second convex portion and perpendicular to the direction in which the first line extends.

9. The display panel of claim 4, wherein the second portion has first convex portions protruded in a direction toward the second line, and the fourth portion has second convex portions protruded in a direction away from the first line.

10. The display panel of claim 9, wherein first imaginary straight lines passing through the first convex portions and perpendicular to the direction in which the first line extends are spaced apart from second imaginary straight lines passing through the second convex portions and perpendicular to the direction in which the first line extends.

11. The display panel of claim 10, wherein the first imaginary straight lines and the second imaginary straight lines are alternately arranged in the direction in which the first line extends.

12. The display panel of claim 4, wherein the first line includes a driving voltage line and the second line includes a data line.

13. The display panel of claim 4, wherein, when viewed from the direction perpendicular to the substrate, the first line has a fifth portion that overlaps the opening and is spaced apart from the second portion in the opening, wherein the second portion and the fifth portion are connected to the first portion.

14. The display panel of claim 13, wherein, when viewed from the direction perpendicular to the substrate, each of the first portion and the third portion is straight in the direction in which the first line extends, and each of the second portion, the fourth portion, and the fifth portion is curved.

15. The display panel of claim 14, wherein, when viewed from the direction perpendicular to the substrate, each of the second portion, the fourth portion, and the fifth portion is a repeating curve.

16. The display panel of claim 14, wherein the second portion has a first convex portion protruded in a direction toward the second line, the fifth portion has a third convex portion protruded in the direction toward the second line, and the fourth portion has a second convex portion protruded in a direction away from the first line.

17. The display panel of claim 16, wherein a first imaginary straight line passing through the first convex portion and perpendicular to a direction in which the first line extends is spaced apart from a second imaginary straight line passing through the second convex portion and perpendicular to the direction in which the first line extends, and a third imaginary straight line passing through the third convex portion and perpendicular to the direction in which the first line extends coincides with the first imaginary straight line.

18. The display panel of claim 14, wherein the second portion has first convex portions protruded in a direction toward the second line, the fifth portion has third convex portions protruded in the direction toward the second line, and the fourth portion has second convex portions protruded in a direction away from the first line.

19. An electronic apparatus comprising:
a display panel; and
a lower cover constituting an exterior of the electronic apparatus and having an opening portion that exposes a portion of the display panel,
wherein the display panel comprises:
a substrate;
a pixel electrode disposed on the substrate;
a pixel-defining layer having an opening, wherein the pixel-defining layer covers an edge of the pixel electrode, and the opening exposes a center of the pixel electrode; and
a first line positioned between the substrate and the pixel electrode and having a first portion overlapping the pixel-defining layer and a second portion overlapping the opening, wherein, when viewed from a direction perpendicular to the substrate, a shape of the first portion differs from a shape of the second portion.

20. A display panel comprising:
a substrate;
a pixel electrode disposed on the substrate;
a pixel-defining layer configured to define an opening that exposes a portion of the pixel electrode, wherein the pixel-defining layer at least partially covers the pixel electrode; and
a conductive line positioned between the substrate and the pixel electrode, the conductive line including a first region overlapping the pixel-defining layer and a second region overlapping the opening, wherein, in a plan view, the first region has a shape distinct from the shape of the second region.
